(19) United States
(12) Patent Application Publication
(10) Pub. No.: US 2007/0188202 A1
(43) Pub. Date: Aug. 16, 2007

(54) Power control circuit

(75) Inventor: Heng-Chen Kuo, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,866

(22) Filed: Oct. 16, 2006

(30) Foreign Application Priority Data
Jan. 17, 2006 (CN) 200610033273.1

(51) Int. Cl. H03L 7/00

(52) U.S. Cl. 327/142

(57) ABSTRACT

An exemplary power control circuit includes a voltage divider, a switching circuit, and a detecting circuit. The voltage divider receives power from a first power supply which is connected to a microprocessor. The switching circuit is connected between a second power supply and the microprocessor. The detecting circuit is connected between the switching circuit and the voltage divider, the switching circuit is turned on when a divided voltage of the voltage divider is greater than a turn-on voltage of the detecting circuit, and power from the second power supply is supplied to the microprocessor through the switching circuit.

### FIELD OF THE INVENTION

The present invention generally relates to a power control circuit, and particularly to a power up sequencing circuit of a microprocessor.

### DESCRIPTION OF RELATED ART

As microprocessors become faster and provide additional features, more power is consumed by the processors. A typical microprocessor uses split rail designs, requiring two different voltage levels: one for the external or I/O voltage and another for the internal or core voltage. For example, a split rail microprocessor might require 3.3 V for its I/O voltage while requiring a lower core voltage of 2.9 V. In some systems, some components including the microprocessor may operate at one voltage level, and other components, such as I/O components, may operate at another voltage level. Also, a manufacturer may offer different versions of a microprocessor that operate at different voltage levels. Normally the core voltage and the I/O voltage are provided to the microprocessor at the same time, but it is needed for the microprocessor to perform a start-up operation, if the I/O voltage is powered on, but the core voltage is not, malfunction of I/O devices will occur.

What is needed is to provide a power control circuit that adjusts the sequence of supplying power to multiple split rail microprocessors.

### SUMMARY OF THE INVENTION

An exemplary power control circuit includes a voltage divider, a switching circuit, and a detecting circuit. The voltage divider receives a first power supply, which is connected to a microprocessor. The switching circuit is connected between a second power supply and the microprocessor. The detecting circuit is connected between the switching circuit and the voltage divider, the switching circuit is turned on when a divided voltage of the voltage divider is greater than a turn-on voltage of the detecting circuit, and power from the second power supply passes to the microprocessor through the switching circuit.

Other advantages and novel features of the invention will become more apparent from the following detailed description when taken in conjunction with the accompanying drawings, in which:

### BRIEF DESCRIPTION OF THE DRAWINGS

FIG. 1 is a block diagram of a power control circuit in accordance with a preferred embodiment of the present invention, together with a microprocessor; and

FIG. 2 is a circuit diagram of the power control circuit of FIG. 1.

### DETAILED DESCRIPTION OF THE INVENTION

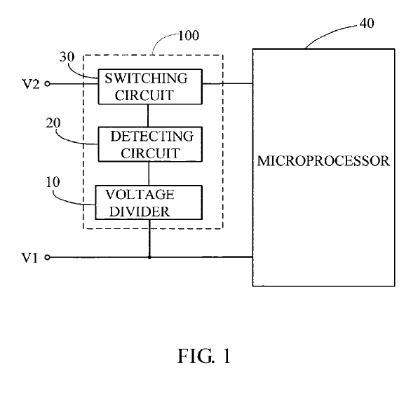

Referring to FIG. 1, a power control circuit 100 in accordance with a preferred embodiment of the present invention includes a switching circuit 30, a detecting circuit 20, and a voltage divider 10. A core power supply V1 is connected to the voltage divider 10 and a microprocessor 40. An I/O power supply V2 is connected to the microprocessor 40 via the switching circuit 30. The detecting circuit 20 is connected between the switching circuit 30 and the voltage divider 10. During operation, the voltage divider 10 produces a divided voltage that is a fraction of a core voltage of the core power supply V1 to the detecting increases, when the output voltage of the voltage divider 10 is higher than a predetermined voltage, the switching circuit 30 is turned on to provide power from the I/O power supply V2 to the microprocessor 40.

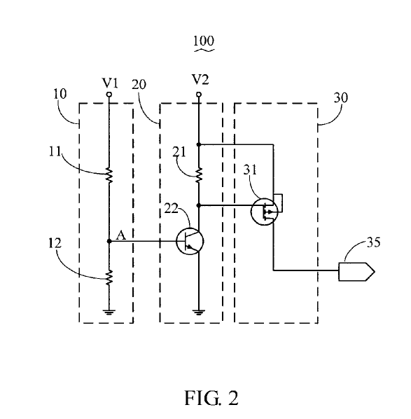

Referring to the detailed circuit diagram of FIG. 2, the voltage divider 10 includes a first resistor 111 and a second resistor 12, and the core power supply V1 is connected to ground via the first resistor 11 and the second resistor 12. A node A between the first resistor 111 and the second resistor 12 acts as the output of the voltage divider 10.

The detecting circuit 20 includes a third resistor 21 and an NPN transistor 22. A base of the NPN transistor 22 is connected to the node A, a collector of the transistor 22 is connected to the I/O power supply V2, and an emitter of the transistor 22 is grounded.

The switching circuit 30 includes a metal oxide semiconductor field effect transistor (MOSFET) transistor 31. A source of the MOSFET transistor 31 is connected the I/O power supply V2, a gate of the MOSFET transistor 31 is connected to the collector of the transistor 22, and a drain of the MOSFET transistor 31 is connected to an I/O pin of the microprocessor 40. The drain of the MOSFET transistor 31 acts as an output 35 of the switching circuit 30.

In operation, the core voltage at the core power supply V1 increases as time passes, before the core voltage increases to a predetermined level, a voltage at the node A is lower than a turn-on voltage of approximately 0.7V of the NPN transistor 22, a voltage at the gate of the MOSFET transistor 31 is equal to an I/O voltage at the I/O power supply V2, and so the MOSFET transistor 31 is turned off, and power from the I/O power supply V2 can not be provided to the microprocessor 40. Thus, during a time before the microprocessor 40 completes the start-up operation, malfunction of I/O devices is prevented.

When the voltage at the node A reaches the turn-on voltage of the transistor 22, the microprocessor 40 completes the start operation, and the transistor 22 is turned on, thereby the MOSFET transistor 31 is also turned on to pass power from the I/O power supply V2 to the microprocessor 40.

As such, the I/O voltage is not supplied to the microprocessor until the core voltage has achieved a desired level. During power up, malfunction of I/O devices due to improper sequencing of supply voltage levels is prevented.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

What is claimed is:

1. A power control circuit comprising:
a voltage divider receiving power from a first power supply which is connected to a microprocessor, the voltage divider generating a divided voltage;
a switching circuit receiving power from a second power supply and connected to the microprocessor; and
a detecting circuit connected between the switching circuit and the voltage divider, wherein the switching circuit is turned on when the divided voltage of the voltage divider is greater than a turn-on voltage of the detecting circuit, and power from the second power supply is supplied to the microprocessor through the switching circuit.

2. The power control circuit as claimed in claim 1, wherein the voltage divider comprises a first resistor and a second resistor, the first resistor and the second resistor are connected in series between the first power supply and ground, and the divided voltage is output at a node between the first resistor and the second resistor.

3. The power control circuit as claimed in claim 2, wherein the detecting circuit comprises a third resistor and an NPN transistor, a base of the NPN transistor receives the divider voltage of the voltage divider, an emitter of the NPN transistor is grounded, and a collector of the NPN transistor is connected to the second power supply via the third resistor, and also connected to the switching circuit.

4. The power control circuit as claimed in claim 1, wherein the switching circuit comprises a metal oxide semiconductor field effect transistor (MOSFET) transistor having a gate connected to the detecting circuit, a source connected to the second power supply, and a drain connected to the microprocessor.

5. The power control circuit as claimed in claim 1, wherein the power from the first power supply is lower than that from the second power supply.

6. A power up sequencing circuit comprising:
a first node adapted to be coupled to an I/O power supply;
a second node adapted to be coupled to a core power supply;
a voltage divider coupled between the first node and ground, the voltage divider having an output;
an NPN transistor having a base coupled to the output of the voltage divider, an emitter coupled to ground, and a collector coupled to the second node through a first resistor; and
a MOSFET transistor having a gate coupled to the collector of the NPN transistor, a source coupled to the second node, and a drain configured for being coupled to a microprocessor.

7. The power up sequencing circuit as claimed in claim 6, wherein the voltage divider comprises a second resistor and a third resistor, the second resistor and the third resistor are connected in series between the first node and ground, and a node between the first resistor and the second resistor acts as the output of the voltage divider.
